(19) United States
(12) Patent Application Publication
(10) Pub. No.: US 2026/0343792 A1
(43) Pub. Date: Oct. 29, 2026

(54) COMPOSITE HEAT DISSIPATION DEVICE

(71) Applicant: PURPLE CLOUD DEVELOPMENT PTE. LTD., Singapore (SG)

(72) Inventors: Shiman XU, Hui Zhou City (CN); Jiasheng LAI, Hui Zhou City (CN)

(73) Assignee: PURPLE CLOUD DEVELOPMENT PTE. LTD., Singapore (SG)

(21) Appl. No.: 19/661,223

(22) Filed: Apr. 28, 2026

(30) Foreign Application Priority Data
Apr. 29, 2025 (CN) 202520856710.8

(51) Int. Cl. H05K 7/20

(52) U.S. Cl. CPC H05K 7/20154; H05K 7/20172

(57) ABSTRACT

A composite heat dissipation device includes a heat dissipation fin unit having a hollow portion, a rotating member disposed on the hollow portion, and a fan unit including a main shaft connected to the rotating member. The fan unit is configured to drive the rotating member to rotate via the main shaft. The heat dissipation fin unit may include a base, a connecting cylinder, and at least one heat dissipation fin. The composite heat dissipation device may further include a thermal conduction cylinder disposed within the connecting cylinder, defining a thermal conduction channel, and an isolation member disposed within the thermal conduction cylinder adjacent to the rotating member. The rotating member may include a ring groove and a first protrusion portion having a curved surface, wherein the curved surface, the first protrusion portion, and the ring groove together define a heat-absorbing surface. The isolation member may include a second protrusion portion and a ring recess.

### RELATED APPLICATIONS

This US application claims priority to Chinese Patent Application No. 2025208567108, filed on Apr. 29, 2025, which is incorporated herein by reference.

### TECHNICAL FIELD

The present disclosure relates to heat dissipation technologies and, more particularly, to a composite heat dissipation device.

### BACKGROUND

Electronic components generate heat during operation, which must be effectively dissipated to ensure maintain consistent performance and longevity. Conventional heat dissipation devices typically absorb heat from a heat source via heat dissipation fins by conductive heat transfer and employ a fan to remove heat from the fins.

However, thermal energy can be transferred not just only via conduction but also via radiation. As data volume and computation demand continues to increase, the thermal load may exceed the cooling capability of conventional arrangements, which rely mostly on fan-assisted dissipation of conducted heat. Accordingly, enhanced heat dissipation devices are desirable.

### SUMMARY

Aspects of the present disclosure provide a composite heat dissipation device. The composite heat dissipation device includes a heat dissipation fin unit having a hollow portion, a rotating member disposed on the hollow portion, and a fan unit including a main shaft, the fan unit being connected to the rotating member by the main shaft. The fan unit is configured to drive the rotating member to rotate via the main shaft.

In some embodiments, the heat dissipation fin unit includes a base, a connecting cylinder secured to the base, the connecting cylinder defining the hollow portion, and at least one heat dissipation fin arranged around the connecting cylinder at intervals, the heat dissipation fin having one end connected to the connecting cylinder.

In some embodiments, the composite heat dissipation device further includes a thermal conduction cylinder secured to the base and disposed within the connecting cylinder. The rotating member being disposed on the thermal conduction cylinder, and the thermal conduction cylinder defines a thermal conduction channel configured to transfer heat toward the rotating member.

In some embodiments, the composite heat dissipation device further includes an isolation member disposed within the thermal conduction cylinder and adjacent to the rotating member, wherein the isolation member is configured to receive heat through the thermal conduction channel and then transfer the received heat to the rotating member.

In some embodiments, the fan unit comprises a hub having the main shaft, a first end of the main shaft being connected to the hub and a second end of the main shaft being connected to the rotating member, and at least one fan blade secured to the hub.

In some embodiments, the composite heat dissipation device further includes a bracket disposed on the heat dissipation fin and located between the rotating member and the hub, wherein the second end of the main shaft passes through the bracket and is connected to the rotating member.

In some embodiments, a top surface of the rotating member defines a connection hole, the second end of the main shaft passes through the bracket and is connected to the connection hole, and a bottom surface of the rotating member defines a ring groove, the ring groove being disposed on upper portions of the connecting cylinder and the thermal conduction cylinder.

In some embodiments, the bottom surface of the rotating member further includes a first protrusion portion, the first protrusion portion having a curved surface, and the curved surface, the first protrusion portion, and the ring groove together defining a heat-absorbing surface.

In some embodiments, a top surface of the isolation member includes a second protrusion portion, and a bottom surface of the isolation member includes a ring recess. In some embodiments, the ring recess is disposed radially inward of the second protrusion portion.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a perspective schematic view of a composite heat dissipation device 1 according to an embodiment of the present disclosure.

FIG. 2 illustrates an exploded view of the composite heat dissipation device 1 as shown in FIG. 1.

FIG. 3 illustrates another exploded view of the composite heat dissipation device 1 as shown in FIG. 1.

FIG. 4 illustrates a cross-sectional view of the composite heat dissipation device 1 as shown in FIG. 1.

FIG. 5 illustrates a partial enlarged view of the heat dissipation fin unit 11 as shown in FIG. 4.

### DETAILED DESCRIPTION

Detailed descriptions and technical contents of the present disclosure are illustrated below in conjunction with the accompanying drawings. However, it is to be understood that the descriptions and the accompanying drawings disclosed herein are merely illustrative and exemplary and not intended to limit the scope of the present disclosure.

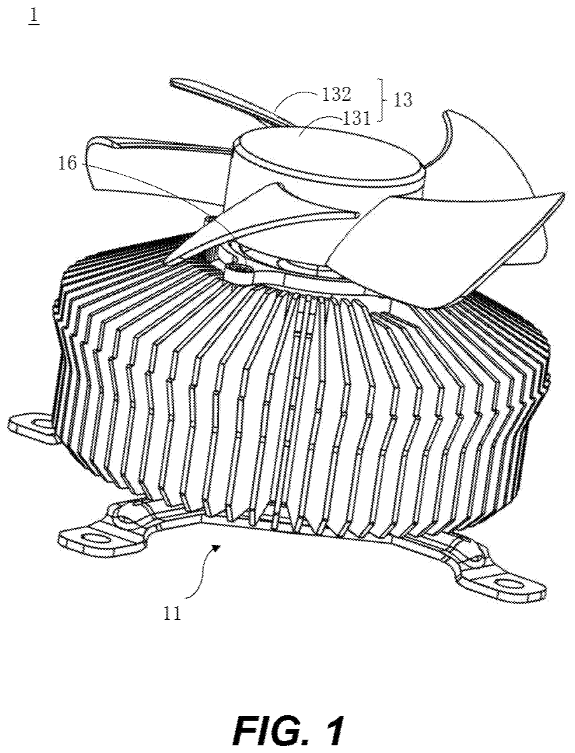

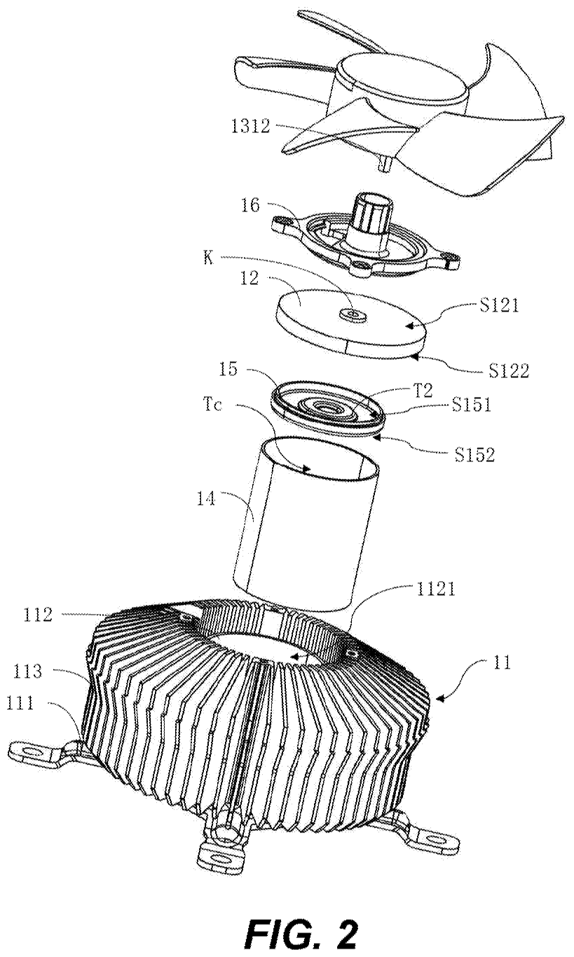

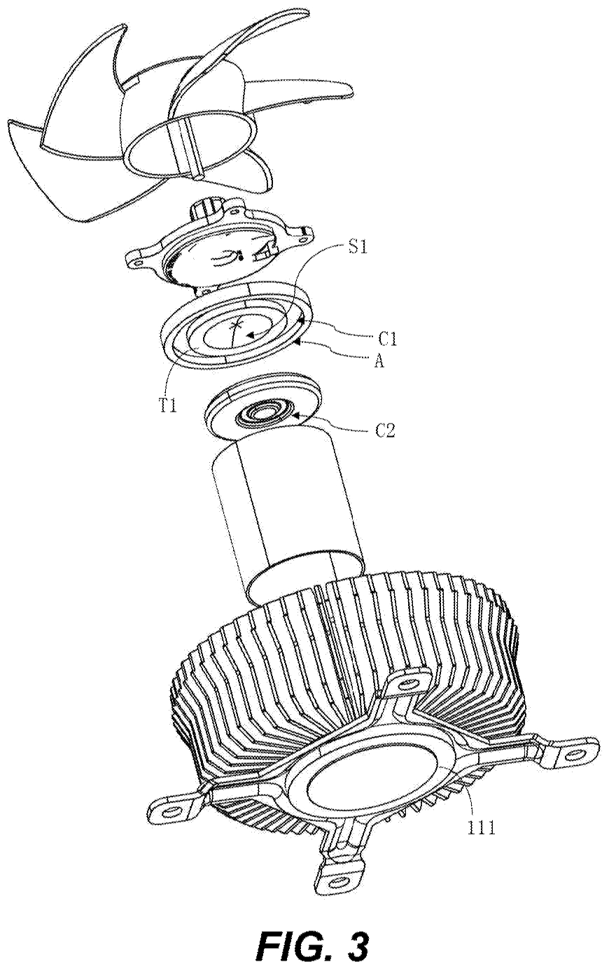

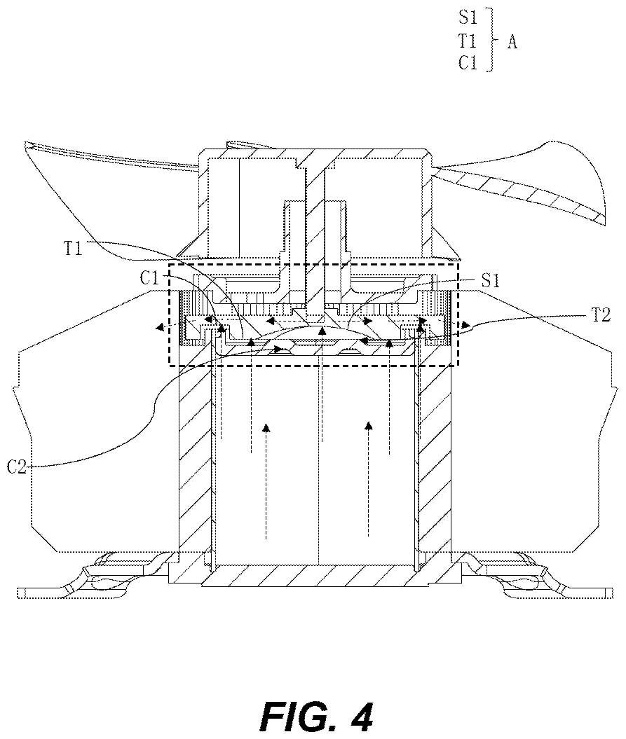

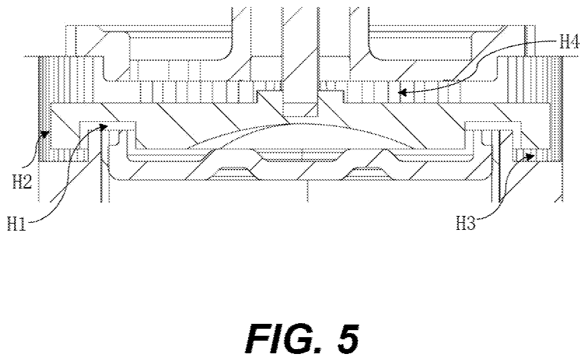

Referring to FIGS. 1 to 5, FIG. 1 is a perspective view of a composite heat dissipation device 1 according to aspects of the present disclosure. FIG. 2 is an exploded view of the composite heat dissipation device 1 shown in FIG. 1. FIG. 3 is another exploded view of the composite heat dissipation device 1 shown in FIG. 1 from a different angle. FIG. 4 is a sectional view of the composite heat dissipation device 1 shown in FIG. 1. FIG. 5 is an enlarged partial view of the region indicated in FIG. 4.

As shown in FIG. 1, the composite heat dissipation device 1 may include a heat dissipation fin unit 11 and a fan unit 13. As shown in FIG. 2, the composite heat dissipation device 1 may further include a rotating member 12 disposed between the heat dissipation fin unit 11 and the fan unit 13. The heat dissipation fin unit 11 has a hollow portion 1121, and the rotating member 12 is disposed on the hollow portion 1121. The fan unit 13 includes a main shaft 1312 connected to the rotating member 12, enabling the rotation of the fan unit 13 to drive the rotation of the rotating member 12.

In some embodiments, the composite heat dissipation device 1 is thermally coupled to a heat source (not shown). For example, the heat source may be disposed adjacent to one lower side of the base 111, and the base 111 may be secured to or placed in thermal contact with the heat source, optionally with a thermal interface material between them. Accordingly, conductive heat from the heat source may be transferred to the heat dissipation fin unit 11 via the base 111, while radiative heat from the heat source may propagate upward through the hollow portion 1121 toward the rotating member 12.

As shown in FIGS. 1 and 2, the heat dissipation fin unit 11 may include a base 111, a connecting cylinder 112, and at least one heat dissipation fin 113. The connecting cylinder 112 is secured to the base 111 and defines the hollow portion 1121. The heat dissipation fin 113 may be arranged around the connecting cylinder 112 at intervals, and one end of each heat dissipation fin 113 is connected to the connecting cylinder 112. In some embodiments, the heat dissipation fin unit 11 includes a plurality of heat dissipation fins 113 arranged circumferentially around the connecting cylinder 112 as shown in FIG. 2.

In some embodiments, the rotating member 12 may be made of copper, iron, aluminum, composite plastic, or another material capable of transferring heat.

As shown in FIGS. 2 and 4, the composite heat dissipation device 1 may further include a thermal conduction cylinder 14. The thermal conduction cylinder 14 is secured to the base 111 and disposed within the connecting cylinder 112, and the rotating member 12 is disposed on the thermal conduction cylinder 14. The thermal conduction cylinder 14 has a thermal conduction channel Tc. During operation, the thermal conduction cylinder 14 receives radiative heat from the heat source and transfers the heat toward the rotating member 12 through the thermal conduction channel Tc. As shown in FIG. 4, the arrows indicate the direction of radiative heat transfer.

As further shown in FIGS. 2 and 4, the composite heat dissipation device 1 may further include an isolation member 15 disposed within the thermal conduction cylinder 14 adjacent to the rotating member 12. Heat generated by the heat source may be transferred by radiation via the thermal conduction channel Tc to the rotating member 12 through the isolation member 15. As the rotating member 12 rotates, heat received by the rotating member 12 can be discharged from the composite heat dissipation device 1.

In some embodiments, the thermal conduction cylinder 14 and the isolation member 15 may be made of copper, iron, aluminum, composite plastic, or another material capable of transferring heat. The material of the thermal conduction cylinder 14 may be the same as or different from the material of the isolation member 15. In some embodiments, the thermal conduction cylinder 14 and the isolation member 15 are integrally formed as a single piece.

As shown in FIGS. 1 and 2, the fan unit 13 includes a hub 131 and at least one fan blade 132. The hub 131 includes a main shaft 1312. A first end of the main shaft 1312 is connected to the hub 131, and a second end of the main shaft 1312 is connected to the rotating member 12. When the hub 131 rotates, it enables the rotating member 12 to rotate through the main shaft 1312. The fan blade 132 is secured to the hub 131 and rotates synchronously with the hub 131.

As further shown in FIGS. 1 and 2, the composite heat dissipation device 1 may further include a bracket 16. The bracket 16 is disposed on the heat dissipation fin unit 11 and between the rotating member 12 and the hub 131. The second end of the main shaft 1312 extends through the bracket 16 and is connected to the rotating member 12.

The top surface S121 of the rotating member 12 is provided with a connection hole K. The second end of the main shaft 1312 passes through the bracket 16 and is connected to the connection hole K. The bottom surface S122 of the rotating member 12 is provided with a ring groove C1. The ring groove C1 is disposed on the upper portions of the connecting cylinder 112 and the thermal conduction cylinder 14. In some embodiments, the top of the connecting cylinder 112 is flush with the top of the thermal conduction cylinder 14. As shown in FIG. 5, a plurality of gaps H1, H2, H3, and H4 are defined between the ring groove C1 and adjacent structures, such as the thermal conduction cylinder 14, the heat dissipation fin 113, and the bracket 16, allowing the rotating member 12 to rotate without interference.

The bottom surface S122 of the rotating member 12 may further include a first protrusion portion T1, and the first protrusion portion T1 may include a curved surface S1. In some embodiments, the curved surface S1 may be an arc-shaped surface curved toward the top surface S121. The curved surface S1, the first protrusion portion T1, and the ring groove C1 together define a heat-absorbing surface A configured to absorb heat from the heat source. The top surface S151 of the isolation member 15 has a second protrusion portion T2, and the bottom surface S152 of the isolation member 15 has a ring recess C2. Heat generated by the heat source may be transferred by radiation to the ring recess C2 and then to the second protrusion portion T2. As shown in FIG. 5, in the some embodiments, the ring recess C2 is disposed radially inward of the second protrusion portion T2. Namely, the ring recess C2 is closer to a central axis of the isolation member 15 than the second protrusion portion T2. This configuration provides the isolation member 15 an M-shaped longitudinal cross-section, however the present disclosure is not limited thereto.

In the composite heat dissipation device of the foregoing embodiment, the rotating member is provided in addition to the fan blade, such that the rotating member and the fan blade enable to work together for enhancing heat dissipation. More specifically, the fan unit promotes convective cooling, while the rotating member assists in removing heat transferred toward the rotating member by radiation. As a result, the overall heat dissipation efficiency of the composite heat dissipation device may be enhanced. In some embodiments, the thermal resistance value can be reduced to about 0.310 °C/W.

Although the present disclosure has been described with reference to the foregoing embodiments, those embodiments are provided for purposes of illustration and are not intended to be limiting. A person having ordinary skill in the art, in view of the present disclosure, will appreciate that various modifications, alternatives, and equivalents may be made without departing from the spirit and scope of the present disclosure. Accordingly, the scope of the present disclosure should be defined by the appended claims and their equivalents.

What is claimed is:

1. A composite heat dissipation device, comprising:
a heat dissipation fin unit having a hollow portion;
a rotating member disposed on the hollow portion; and
a fan unit including a main shaft, the fan unit being connected to the rotating member by the main shaft,
wherein the fan unit is configured to drive the rotating member to rotate via the main shaft.

2. The composite heat dissipation device of claim 1, wherein the heat dissipation fin unit comprises:
a base;
a connecting cylinder secured to the base, the connecting cylinder defining the hollow portion; and
at least one heat dissipation fin arranged around the connecting cylinder at intervals, the heat dissipation fin having one end connected to the connecting cylinder.

3. The composite heat dissipation device of claim 2, further comprising a thermal conduction cylinder secured to the base and disposed within the connecting cylinder, the rotating member being disposed on the thermal conduction cylinder, wherein the thermal conduction cylinder defines a thermal conduction channel configured to transfer heat toward the rotating member.

4. The composite heat dissipation device of claim 3, further comprising an isolation member disposed within the thermal conduction cylinder and adjacent to the rotating member, wherein the isolation member is configured to receive heat through the thermal conduction channel and then transfer the received heat to the rotating member.

5. The composite heat dissipation device of claim 4, wherein the fan unit comprises a hub having the main shaft, a first end of the main shaft being connected to the hub and a second end of the main shaft being connected to the rotating member, and at least one fan blade secured to the hub.

6. The composite heat dissipation device of claim 5, further comprising a bracket disposed on the heat dissipation fin and located between the rotating member and the hub, wherein the second end of the main shaft passes through the bracket and is connected to the rotating member.

7. The composite heat dissipation device of claim 5, wherein a top surface of the rotating member defines a connection hole, the second end of the main shaft passes through the bracket and is connected to the connection hole, and a bottom surface of the rotating member defines a ring groove, the ring groove being disposed on upper portions of the connecting cylinder and the thermal conduction cylinder.

8. The composite heat dissipation device of claim 7, wherein the bottom surface of the rotating member further includes a first protrusion portion, the first protrusion portion having a curved surface, and the curved surface, the first protrusion portion, and the ring groove together defining a heat-absorbing surface.

9. The composite heat dissipation device of claim 5, wherein a top surface of the isolation member includes a second protrusion portion, and a bottom surface of the isolation member includes a ring recess.

10. The composite heat dissipation device of claim 9, wherein the ring recess is disposed radially inward of the second protrusion portion.
